(19) United States
(12) Patent Application Publication
(10) Pub. No.: US 2026/0186365 A1
(43) Pub. Date: Jul. 2, 2026

(54) OPTICAL SHUTTER PANEL AND METHOD OF DRIVING THE SAME

(71) Applicant: LG Display Co., Ltd., Seoul (KR)

(72) Inventors: Dong Il YU, Paju-si (KR); Min Soo PARK, Paju-si (KR); Sang Hyun LEE, Paju-si (KR)

(21) Appl. No.: 19/434,312

(22) Filed: Dec. 29, 2025

(30) Foreign Application Priority Data
Dec. 31, 2024 (KR) 10-2024-0202602

(51) Int. Cl. G02F 1/1676

(52) U.S. Cl. CPC G02F 1/1676

(57) ABSTRACT

An optical shutter panel and a method of driving the same. A display panel can be disposed on the optical shutter panel. The optical shutter panel can realize one of a light-blocking mode and a light-transmission mode, according to an operation of the display panel. In changing from light-blocking mode to the light-transmission mode, a voltage higher than a reference voltage applied to a second shutter electrode layer of the optical shutter panel and a voltage lower than the reference voltage are alternately applied to the first shutter electrode layer. A time duration during which a voltage lower than the reference voltage applied to the first shutter electrode layer is shorter than a time duration during which a voltage higher than the reference voltage applied to the first shutter electrode layer. Thus, in the optical shutter panel, a transmittance in the light-transmission mode can be improved.

### CROSS-REFERENCE TO RELATED APPLICATIONS

Pursuant to 35 U.S.C. § 119(a), this application claims the benefit of an earlier filing date and right of priority to Korean Patent Application No. 10-2024-020602, filed on December 31, 2024, the entire content of which is hereby incorporated by reference as if fully set forth herein.

### TECHNICAL FIELD

The present disclosure relates to an optical shutter panel.

### BACKGROUND

Generally, a display apparatus provides an image to a user. For example, the display apparatus can include a display panel. The display panel can include light-emitting devices disposed on a device substrate. Each of the light-emitting devices can emit light displaying a specific color. For example, each of the light-emitting devices can include a light-emitting unit between a first electrode and a second electrode.

### SUMMARY

An optical shutter panel includes a first shutter substrate. A second shutter substrate is disposed on the first shutter substrate. An electronic ink layer is disposed between the first shutter substrate and the second shutter substrate. A first shutter electrode layer is disposed between the first shutter substrate and the electronic ink layer. The first shutter electrode layer includes first electrode patterns and second electrode patterns. A shutter insulating layer is disposed between the first shutter electrode layer and the electronic ink layer. The shutter insulating layer includes shutter holes. The shutter holes overlap with the first electrode patterns. A second shutter electrode layer is disposed between the electronic ink layer and the second shutter substrate. The second electrode patterns are disposed between the shutter holes. The second electrode patterns are insulated from the first electrode patterns.

In another implementation, there is provided a method of driving an optical shutter panel including realizing a light-blocking mode by applying a light-blocking voltage lower than a voltage applying the second shutter electrode layer to the first shutter electrode layer, changing the light-blocking mode to a first intermediate mode by applying a first voltage higher than the voltage applying the second shutter electrode to the first shutter electrode layer for a first time duration, changing the first intermediate mode to a second intermediate mode by applying a second voltage lower than the voltage applying the second shutter electrode layer to the first shutter electrode layer for a second time duration, changing the second intermediate mode to a third intermediate mode by applying a third voltage higher than the voltage applying the second shutter electrode layer to the first shutter electrode layer for a third time duration, and realizing a light-transmission mode by applying a light-transmission voltage higher than the voltage applying the second shutter electrode layer to the first shutter electrode layer. The second time duration is shorter than the first time duration and the third time duration.

### BRIEF DESCRIPTION OF THE DRAWINGS

The accompanying drawings, which are included to provide a further understanding of the present disclosure and are incorporated in and constitute a part of this application, illustrate implementation(s) of the present disclosure and together with the description serve to explain the principle of the present disclosure. In the drawings:

FIG. 1 is a view schematically showing an example of a display apparatus according to an implementation of the present disclosure;

FIG. 2 is an enlarged view of an example of the K1 region in FIG. 1;

FIG. 3 is a view showing an example of a circuit of a pixel area in the display apparatus according to the implementation of the present disclosure;

FIG. 4 is a view showing an example of a cross-section taken along I-I’ line of FIG. 2;

FIG. 5 is an enlarged view of an example of the K2 region in FIG. 4;

FIG. 6 is a waveform diagram showing an example of voltages of signals applied to the first shutter electrode layer and the second shutter electrode layer in the display device according to the implementation of the present disclosure, when the optical shutter panel is switched from the light-blocking mode to the light-transmission mode;

FIGS. 7 to 12 are views sequentially showing an example of a location of electronic ink particles, when the optical shutter panel is switched from the light-blocking mode to the light-transmitting mode in the display device according to the implementation of the present disclosure;

FIG. 13 is a graph showing an example of transmittances of a light-transmitting mode according to a method of switching the optical shutter panel from the light-blocking mode to the light-transmission mode;

FIGS. 14 to 17 are views showing an example of the optical shutter panel according to another implementation of the present disclosure; and

FIGS. 18 and 19 are waveform diagrams showing an example of voltages of signals applied to the first shutter electrode layer and the second shutter electrode layer, when the optical shutter panel is switched from the light-blocking mode to the light-transmitting mode in the display device according to another implementation of the present disclosure.

### DETAILED DESCRIPTION

Implementations of the present disclosure can provide an optical shutter panel in which a light-blocking mode and a light-transmission mode can be selectively realized, and a method of driving the same.

When the image is not realized by the display panel, the display apparatus can be recognized as a transparent glass by the user. For example, the device substrate can include transmission areas that do not overlap with the light-emitting devices. Thus, in the display apparatus, light passing through the transmission areas can enable an object behind the display apparatus to be viewed by the user, when the image is not realized by the display panel.

In the display apparatus, the display panel can be disposed on an optical shutter panel. The optical shutter panel can realize one of a light-blocking mode and a light-transmission mode according to an operation of the display panel. For example, when the display realizes the image, the optical shutter panel can realize the light-blocking mode in which external light is blocked. Thus, in the display apparatus, visibility of the image realized by the display panel can be improved.

Implementations of the present disclosure can provide an optical shutter panel capable of improving a transmittance in a light-transmission mode, and a method of driving the same.

Implementations of the present disclosure can provide an optical shutter panel in which electronic ink particles disposed outside shutter holes can be minimized, and a method of driving the same.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

Hereinafter, details related to the above objects, technical configurations, and operational effects of the implementations of the present disclosure will be clearly understood by the following detailed description with reference to the drawings, which illustrate some implementations of the present disclosure. Here, the implementations of the present disclosure are provided in order to allow the technical sprit of the present disclosure to be satisfactorily transferred to those skilled in the art, and thus the present disclosure may be embodied in other forms and is not limited to the implementations described below.

In addition, the same or extremely similar elements may be designated by the same reference numerals throughout the specification and in the drawings, the lengths and thickness of layers and regions may be exaggerated for convenience. It will be understood that, when a first element is referred to as being "on" a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular implementations, and are not intended to limit the scope of the present disclosure. For example, an element described in the singular form is intended to include a plurality of elements unless the context clearly indicates otherwise. In addition, in the specification of the present disclosure, it will be further understood that the terms "comprises" and "includes" specify the presence of stated features, integers, steps, operations, elements, components, and/or combinations thereof, but do not preclude the presence or addition of one or more other features, integers, steps, operations, elements, components, and/or combinations.

And, unless 'directly' is used, the terms "connected" and "coupled" may include that two components are "connected" or "coupled" through one or more other components located between the two components.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### (Implementation)

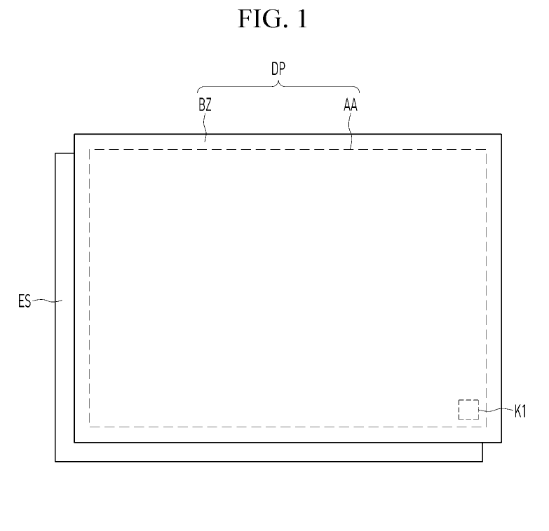

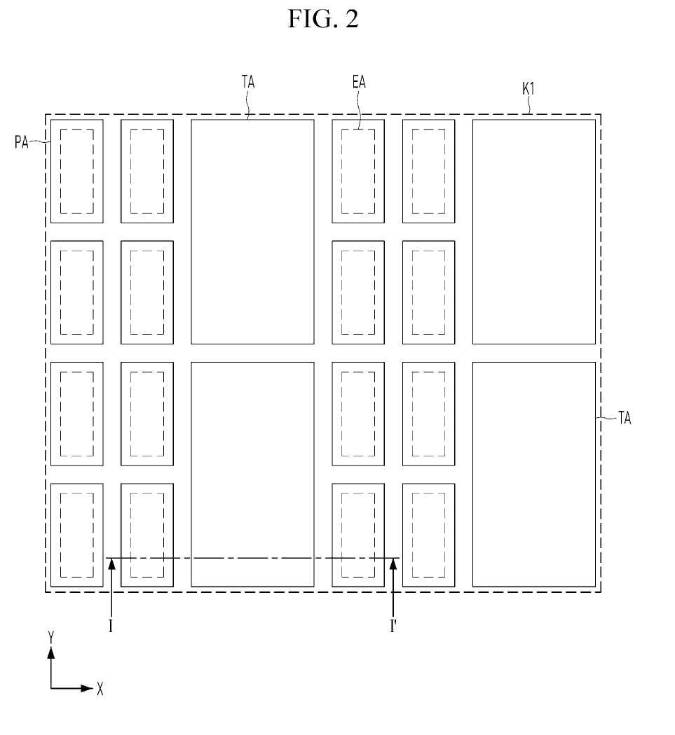

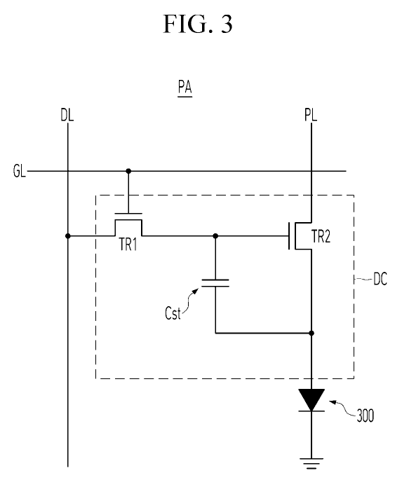

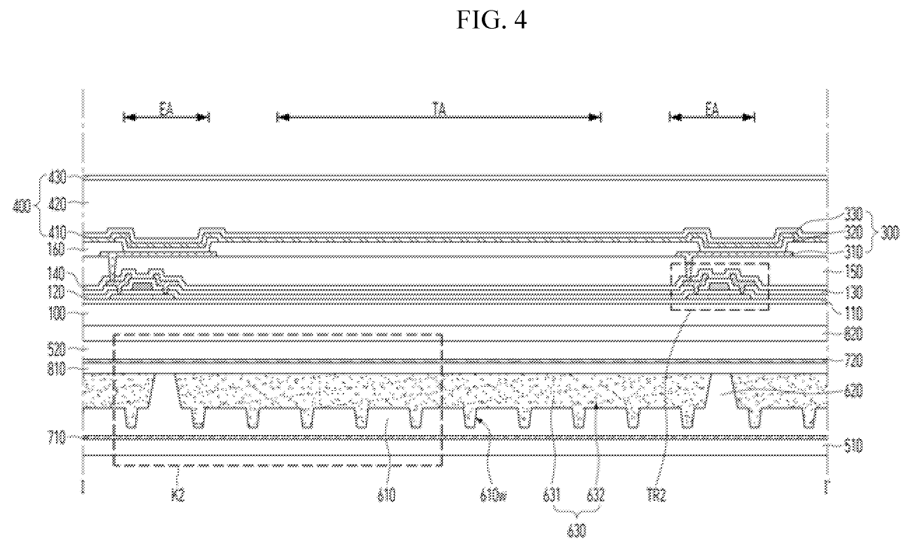

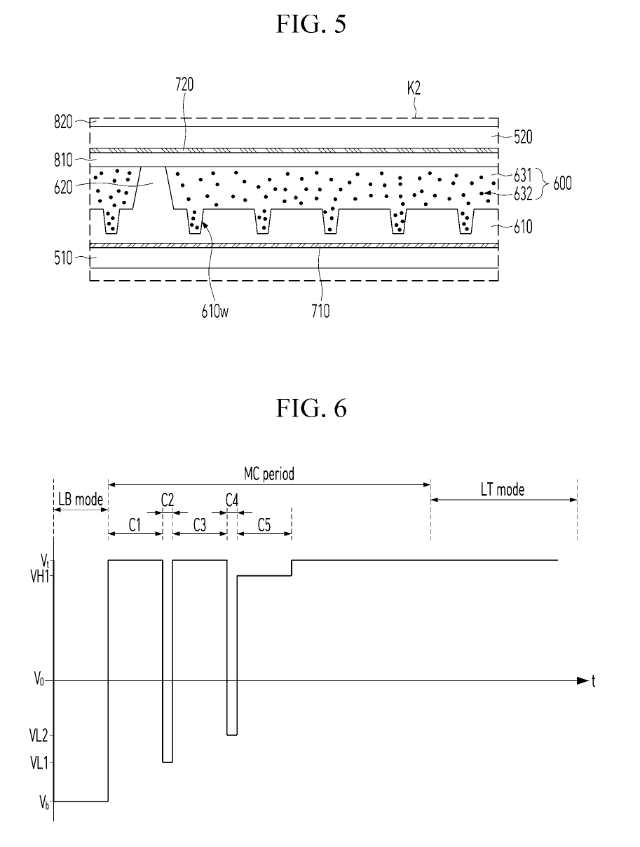

FIG. 1 is a view schematically showing a display apparatus according to an implementation of the present disclosure. FIG. 2 is an enlarged view of K1 region in FIG. 1. FIG. 3 is a view showing a circuit of a pixel area in the display apparatus according to the implementation of the present disclosure. FIG. 4 is a view showing a cross-section taken along I-I’ line of FIG. 2. FIG. 5 is an enlarged view of K2 region in FIG. 4.

Referring to FIGS. 1 to 5, the display apparatus according to the implementation of the present disclosure can include a display panel DP disposed on an optical shutter panel ES. The display panel DP can generate an image provided to a user. For example, pixel areas PA can be disposed within the display panel DP. Each of the pixel areas PA can display various colors. Various signals can be applied to each pixel area PA through signal wirings GL, DL and PL. For example, each of the pixel areas PA can include a driving circuit DC electrically connected to the signal wiring GL, DL and PL, and a light-emitting device 300 electrically connected to the driving circuit DC.

The signal wirings GL, DL and PL can include a gate line GL applying a gate signal, a data line DL applying a data signal, and a power voltage supply line PL supplying a power voltage. For example, the driving circuit DC can provide a driving circuit according to the data signal according to the gate signal to the light-emitting device 300 using the power voltage. The driving current provided to the light-emitting device 300 by the driving circuit DC can be maintained from one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal using the power voltage. For example, the second thin film transistor TR2 can function as a driving thin film transistor. The second thin film transistor TR2 can include a second semiconductor region, a second gate electrode, a second drain electrode and a second source electrode. For example, the second gate electrode can be electrically connected to the first source electrode, and the second drain electrode can be electrically connected to the power voltage supply line PL.

The second semiconductor pattern can include a drain region electrically connected to the second drain electrode, a source region electrically connected to the second source electrode, and a channel region disposed between the drain region and the source region. The channel region of the second semiconductor pattern can overlap with the second gate electrode. The second gate electrode can be insulated from the second semiconductor pattern. For example, the channel region of the second semiconductor pattern can have an electrical conductivity corresponding to a voltage of a signal applied to the second gate electrode.

The voltage of the signal applied to the second gate electrode can be maintained by the storage capacitor Cst for one frame. The storage capacitor Cst can have a stacked structure of capacitor electrodes. For example, the storage capacitor Cst can have a stacked structure of a first capacitor electrode electrically connected to the second gate electrode and a second capacitor electrode electrically connected to the second source electrode.

The driving circuit DC of each pixel area PA can be supported by a device substrate 100. The device substrate 100 can include an insulating material. For example, the device substrate 100 can include glass or plastic. At least one insulating layer, such as buffer insulating layer 110, gate insulating layer 120, interlayer insulating layer 130, device passivation layer 140, planarization layer 150 and bank insulating layer 160, for preventing unintended electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed close to the device substrate 100. The buffer insulating layer 110 can prevent pollution due to the device substrate 100 in a process of forming the driving circuit DC of each pixel area PA. For example, an upper surface of the device substrate 100 toward the driving circuit DC of each pixel area PA can be covered by the buffer insulating layer 110. The driving circuit DC of each pixel area PA can be disposed on the buffer insulating layer 110.

The gate insulating layer 120 can be disposed on the buffer insulating layer 110. The second gate electrode of each pixel area PA can be insulated from the second semiconductor pattern of the corresponding pixel area PA by the gate insulating layer 120. For example, the first semiconductor pattern and the second semiconductor pattern of each pixel area PA can be disposed between the buffer insulating layer 110 and the gate insulating layer 120.

The interlayer insulating layer 130 can be disposed on the gate insulating layer 120. The second drain electrode and the second source electrode of each pixel area PA can be insulated from the second gate electrode of the corresponding pixel area PA by the interlayer insulating layer 130. For example, the first gate electrode and the second gate electrode of each pixel area PA disposed on the gate insulating layer 120 can be covered by the interlayer insulating layer 130.

The device passivation layer 140 can be disposed on the interlayer insulating layer 130. The device passivation layer 140 can prevent a damage of the driving circuit DC in each pixel area PA due to moisture and impact. For example, the first drain electrode, the first source electrode, the second drain electrode and the second source electrode of pixel area PA can be disposed between the interlayer insulating layer 130 and the device passivation layer 140.

The planarization layer 150 can be disposed on the device passivation layer 140. A thickness difference due to the driving circuit DC of each pixel area PA can be removed by the planarization layer 150. For example, an upper surface of the planarization layer 150 opposite to the device substrate 100 can be flat. The planarization layer 150 can include a material having a higher fluidity than the buffer insulating layer 110, the gate insulating layer 120, the interlayer insulating layer 130 and the device passivation layer 140. For example, the buffer insulating layer 110, the gate insulating layer 120, the interlayer insulating layer 130 and the device passivation layer 140 can be an inorganic insulating layer made of an inorganic insulating material, and the planarization layer 150 can be an organic insulating layer made of an organic insulating material.

The light-emitting device 300 of each pixel area PA can be disposed on the upper surface of the planarization layer 150. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the planarization layer 130.

The light-emitting unit 320 can generate light having luminance corresponding to a voltage difference between the first electrode 310 and the second electrode 330. For example, the light-emitting unit 320 can include at least one emission material layer (EML). The first electrode 310 can include a conductive material. The second electrode 330 can include a different material from the first electrode 310. For example, the first electrode 310 can be a reflective electrode including a metal, such as aluminum (Al) and silver (Ag), and the second electrode 330 can be transparent electrodes made of a transparent conductive material, such as ITO and IZO. Thus, in the display apparatus according to the implementation of the present disclosure, the light generated by the light-emitting unit 320 can be emitted through the second electrode 330.

The bank insulating layer 160 can be disposed on the planarization layer 150. The bank insulating layer 160 can include an insulating material. For example, the bank insulating layer 160 can be an organic insulating layer made of an organic insulating material. An edge of the first electrode 310 in each pixel area PA can be covered by the bank insulating layer 160. For example, the first electrode 310 of each pixel area PA can insulated from the first electrode 310 of adjacent pixel area PA by the bank insulating layer 160. The bank insulating layer 160 can define an emission area EA in which light is generated in each pixel area PA. For example, the light-emitting unit 320 of each pixel area PA can be in direct contact with the first electrode 310 and the second electrode 330 of the corresponding pixel area PA within the emission area EA of the corresponding pixel area PA.

An encapsulation structure 400 can be disposed on the light-emitting device 300 of each pixel area PA. The encapsulation structure 400 can prevent a damage of the light-emitting devices 300 in each pixel area PA due to external moisture and impact. The encapsulation structure 400 can have a multi-layer structure. For example, the encapsulation structure 400 can include a first encapsulating layer 410, a second encapsulating layer 420 and a third encapsulating layer 430, which are sequentially stacked. The second encapsulating layer 420 can include a material having a higher fluidity than the first encapsulating layer 410 and the third encapsulating layer 430. For example, the first encapsulating layer 410 and the third encapsulating layer 430 can be an inorganic encapsulating layer made of an inorganic insulating material, and the second encapsulating layer 420 can be an organic encapsulating layer made of an organic insulating material. An upper surface of the encapsulation structure 400 opposite to the device substrate 100 can be a flat.

In the display apparatus according to the implementation of the present disclosure, the display panel DP can be recognized as glass by the user, when the image is not realized by the emission area EA of each pixel area PA. For example, the display apparatus according to the implementation of the present disclosure can be a transparent display apparatus. The display panel DP can include transmission areas TA through which external light incident through the device substrate 100 passes. The transmission areas TA can be disposed between the emission areas EA. For example, in the display apparatus according to the implementation of the present disclosure, at least one emission area EA can be disposed between the transmission areas adjacent in a first direction X, each of the transmission areas TA can extend in a second direction Y perpendicular to the first direction X, and the emission areas EA can be disposed side by side in the second direction, as shown in FIGS. 2 and 4. Thus, in the display apparatus according to the implementation of the present disclosure, an actual object by light passing through the transmission areas can be recognized by the user, when the image is not realized by the display panel.

The buffer insulating layer 110, the gate insulating layer 120, the interlayer insulating layer 130, the device passivation layer 140, the planarization layer 150, the bank insulating layer 160, the first encapsulating layer 410, the second encapsulating layer 420 and the third encapsulating layer 430 can be stacked on each transmission area TA of the device substrate 100. The driving circuit DC and the first electrode 310 of each pixel area PA cannot overlap with the transmission areas TA. For example, the transmission areas TA can be defined outside the first semiconductor pattern, the first gate electrode, the first drain electrode, the first source electrode, the second semiconductor pattern, the second gate electrode, the second drain electrode, the second source electrode, the first electrode and the light-emitting unit of each pixel area PA. Thus, in the display apparatus according to the implementation of the present disclosure, loss or distortion of the light passing through the transmission areas TA due to the driving circuit DC and the first electrode 310 of each pixel area PA can be prevented.

As shown in FIG. 1, in the display apparatus according to the implementation of the present disclosure, the display panel DP can include an active area AA and a bezel area BZ disposed outside the active area AA. The pixel areas PA and the transmission areas TA can be disposed within the active area AA. The active area AA can be surrounded by the bezel area BZ. A gate driver electrically connected to the gate line GL, a data driver electrically connected to the data line DL, and a power unit electrical connected to the power voltage supply line PL can be disposed outside the active area AA. For example, the signal wirings GL, DL and PL can be electrically connected to the driving circuit DC of each pixel area PA through the bezel area BZ.

Light passing through the optical shutter panel ES can be introduced into each transmission area TA of the display panel DP. The optical shutter panel ES can realize one of the light-blocking mode in which light is blocked and the light-transmission mode through which light is passes according to an operation of the display panel DP. For example, in the display apparatus according to the implementation of the present disclosure, the optical shutter panel ES can realize the light-blocking mode, when the light is emitted from the light-emitting devices 300 of the display panel DP. Thus, in the display apparatus according to the implementation of the present disclosure, the transmission areas TA of the display panel DP can be recognized as opaque area by the user, when the light is emitted from the light-emitting device 300 of the display panel DP. That is, in the display apparatus according to the implementation of the present disclosure, deterioration of the image realized by the light-emitting devices 300 due to the light passing through the transmission areas TA can be prevented. Therefore, in the display apparatus according to the implementation of the present disclosure, visibility of the image realized by the display panel DP can be improved.

As shown in FIGS. 4 and 5, in the display apparatus according to the implementation of the present disclosure, the optical shutter panel ES can include a first shutter substrate 510 and a second shutter substrate 520. The display panel DP can be disposed on an outer surface of the first shutter substrate 510 or an outer surface of the second shutter substrate 520. For example, in the display apparatus according to the implementation of the present disclosure, the device substrate 100 can be attached to the second shutter substrate 520 by a substrate adhesive layer 820.

The first shutter substrate 510 and the second shutter substrate 520 can include an insulating material. The first shutter substrate 510 and the second shutter substrate 520 can include a transparent material. For example, the first shutter substrate 510 and the second shutter substrate 520 can include glass or plastic. The second shutter substrate 520 can include a same material as the first shutter substrate 510.

A shutter insulating layer 610 can be disposed between the first shutter substrate 510 and the second shutter substrate 520. For example, the shutter insulating layer 610 can be disposed on an upper surface of the first shutter substrate 510 toward the second shutter substrate 520. The shutter insulating layer 610 can extend along the upper surface of the first shutter substrate 510. The shutter insulating layer 610 can include an insulating material. The shutter insulating layer 610 can include a transparent material. For example, the shutter insulating layer 610 can include an organic insulating material. an upper surface of the shutter insulating layer 610 toward the second shutter substrate 520 can be flat.

The shutter insulating layer 610 can include shutter holes 610w. Each of the shutter holes 610w can have a same size as adjacent shutter holes 610w. For example, a depth and a width of each shutter hole 610w can be a same as a depth and a width of adjacent shutter hole 610w. Each of the shutter holes 610W can be formed simultaneously with adjacent shutter hole 610w. For example, a process of forming the shutter insulating layer 610 can include a step of forming an insulating material layer on the upper surface of the first shutter substrate 510, a step of forming a mask pattern on the insulating material layer, and a step of forming the shutter holes 610w by a process of patterning the insulating material layer using the mask pattern. An upper surface of the shutter insulating layer 610 disposed between adjacent shutter holes 610w can have a larger width than each shutter hole 610w.

Shutter spacers 620 can be disposed between the shutter insulating layer 610 and the second shutter substrate 520. The shutter spacers 620 can be spaced apart from the shutter holes 610w. For example, the shutter holes 610w can be disposed between the shutter spacers 620. The shutter spacers 620 can be arranged at regular intervals. For example, in the display apparatus according to the implementation of the present disclosure, the number of the shutter holes 610w disposed between adjacent shutter spacers 620 can be constant.

The shutter spacers 620 can include an insulating material. The shutter spacers 620 can include a transparent material. For example, the shutter spacers 620 can include an organic insulating material. The shutter spacers 620 can include a same material as the shutter insulating layer 610. A lower surface of each shutter spacer 620 toward the first shutter substrate 510 can be in direct contact with the shutter insulating layer 610. For example, a boundary between the shutter insulating layer 610 and each shutter spacer 620 cannot be recognized.

The shutter spacers 620 cannot overlap with the transmission areas TA of the display panel DP. For example, the shutter spacers 620 can overlap with the emission areas EA of the display panel DP. An interval between adjacent shutter spacers 620 can be larger than a width of each transmission area TA. Thus, in the display apparatus according to the implementation of the present disclosure, the light refracted by the shutter spacers 620 cannot pass through the transmission areas TA. Therefore, in the display apparatus according to the implementation of the present disclosure, the distortion of the actual object recognized by the user due to the light passing through the transmission areas TA can be prevented.

An electronic ink layer 630 can be disposed between the shutter spacers 620. The electronic ink layer 630 can be disposed between the shutter insulating layer 610 and the second shutter substrate 520. The shutter holes 610w of the shutter insulating layer 610 can overlap with the electronic ink layer 630. For example, each of the shutter holes 610w can be filled by the electronic ink layer 630. The electronic ink layer 630 can include a plurality of electronic ink particles 632 dispersed within a fluid layer 631. The fluid layer 631 can include a transparent material. For example, the fluid layer 631 can be a liquid that is not charged with a specific polarity, such as pure water.

The electronic ink particles 632 can be charge with a specific polarity. For example, the electronic ink particles 632 can be charge with a negative polarity. Thus, in the display apparatus according to the implementation of the present disclosure, the electronic ink particles 632 can move according to an electronic field formed between the first shutter substrate 510 and the second shutter substrate 520. Each of the electronic ink particles 632 can be formed of black ink. For example, the external light passing through the upper surface of the shutter insulating layer 610 can be refracted and/or reflected by each electronic ink particle 632. Therefore, in the display apparatus according to the implementation of the present disclosure, a transmittance of the electronic ink layer 630 can be changed by an arrangement of the electronic ink particles 632 in the electronic ink layer 630. That is, in the display apparatus according to the implementation of the present disclosure, a luminance of the external light passing through the electronic ink layer 630 and travelling toward the transmission areas TA can vary depending on an electric field applied to the electronic ink layer 630.

A first shutter electrode layer 710 can be disposed between the first shutter substrate 510 and the shutter insulating layer 610. The first shutter electrode layer 710 can extend along the first shutter substrate 510 and the shutter insulating layer 610. For example, the first shutter electrode layer 710 can include a region overlapping with the shutter spacers 620 and a region overlapping with the electronic ink layer 630. The first shutter electrode layer 710 can include a conductive material. The first shutter electrode layer 710 can include a transparent material. For example, the first shutter electrode layer 710 can be a transparent electrode made of a transparent conductive material, such ITO and IZO.

A lower surface of the shutter insulating layer 610 toward the first shutter substrate 510 can be in direct contact with the first shutter electrode layer 710. A depth of each shutter hole 610w can be smaller than a thickness of the shutter insulating layer 610. Thus, in the display apparatus according to the implementation of the present disclosure, the shutter holes 610w of the shutter insulating layer 610 cannot expose an upper surface of the first shutter electrode layer 710 toward the electronic ink layer 630. Therefore, in the display apparatus according to the implementation of the present disclosure, a damage of the first shutter electrode layer 710 due to the electronic ink particles 632 moving by the electric field applied to the electronic ink layer 630 can be prevented.

A second shutter electrode 720 can be disposed between the electronic ink layer 630 and the second shutter substrate 520. The second shutter electrode layer 720 can overlap with the first shutter electrode layer 710. The second shutter electrode layer 720 can extend between each shutter spacer 620 and the second shutter substrate 520. For example, the second shutter electrode layer 720 can include a region overlapping with the shutter spacers 620 and a region overlapping with the electronic ink layer 630. A size of the second shutter electrode layer 720 can be a same as a size of the first shutter electrode layer 710. The second shutter electrode layer 720 can include a conductive material. The second shutter electrode layer 720 can include a transparent material. For example, the second shutter electrode layer 720 can be a transparent electrode made of a transparent conductive material, such as ITO and IZO. The second shutter electrode layer 720 can include a same material as the first shutter electrode layer 710.

A signal applied to the second shutter electrode layer 720 can be different from a signal applied to the first shutter electrode layer 710. For example, an electric field by a voltage difference between the first shutter electrode layer 710 and the second shutter electrode layer 720 can be applied to the electronic ink layer 630. That is, in the display apparatus according to the implementation of the present disclosure, the electronic ink particles 632) of the electronic ink layer 630 can move according to the voltage difference between the first shutter electrode layer 710 and the second shutter electrode layer 720. Thus, in the display apparatus according to the implementation of the present disclosure, the optical shutter panel ES can realize the light-blocking mode or the transmission mode by adjusting the voltage difference between the first shutter electrode layer 710 and the second shutter electrode layer 720.

A shutter adhesive layer 810 can be disposed between the electronic ink layer 630 and the second shutter electrode layer 720. The shutter adhesive layer 810 can extend between each shutter spacer 620 and the second shutter electrode layer 720. For example, the shutter adhesive layer 810 can include a region overlapping with the shutter spacers 620 and a region overlapping with the electronic ink layer 630. Thus, in the display apparatus according to the implementation of the present disclosure, the second shutter electrode layer 720 can be spaced apart from the electronic ink electrode 630. Therefore, in the display apparatus according to the implementation of the present disclosure, a damage of the second shutter electrode layer 720 due to the movement of the electronic ink particles 632 can be prevented.

The shutter adhesive layer 810 can include an adhesive material. For example, the shutter adhesive layer 810 can be in direct contact with the lower surface of the second shutter electrode layer 720. An upper surface of each shutter spacer 620 toward the second shutter electrode 720 can be in direct contact with the shutter adhesive layer 810. Thus, in the display apparatus according to the implementation of the present disclosure, the second shutter substrate 520 and the second shutter electrode layer 720 can be attached to the first shutter substrate 510 in which the shutter spacers 620 and the electronic ink layer 630 are formed by the shutter adhesive layer 810. Therefore, in the display apparatus according to the implementation of the present disclosure, an interval between the first shutter electrode layer 710 and the second shutter electrode layer 720 can be maintained by the shutter spacers 620. And, in the display apparatus according to the implementation of the present disclosure, a process of coupling the first shutter substrate 510 and the second shutter substrate 520 can be simplified.

An upper surface of the electronic ink layer 630 toward the second shutter electrode layer 720 can be in direct contact with the shutter adhesive layer 810. For example, an air-gap cannot be formed between the electronic ink layer 630 and the shutter adhesive layer 810. The shutter adhesive layer 810 can be a linear layer having a constant thickness. That is, in the display apparatus according to the implementation of the present disclosure, the upper surface of the electronic ink layer 630 can be parallel to the lower surface of the second shutter electrode layer 720. Thus, in the display apparatus according to the implementation of the present disclosure, the upper surface of the electronic ink layer 630 can have a same level between the shutter spacers 620. For example, in the display apparatus according to the implementation of the present disclosure, a distance between the upper surface of the electronic ink layer 630 and the lower surface of the second shutter electrode layer 720 can be constant between the shutter spacers 620. Therefore, in the display apparatus according to the implementation of the present disclosure, a refraction deviation of the external light due to a shape of the upper surface of the electronic ink layer 630 can be prevented.

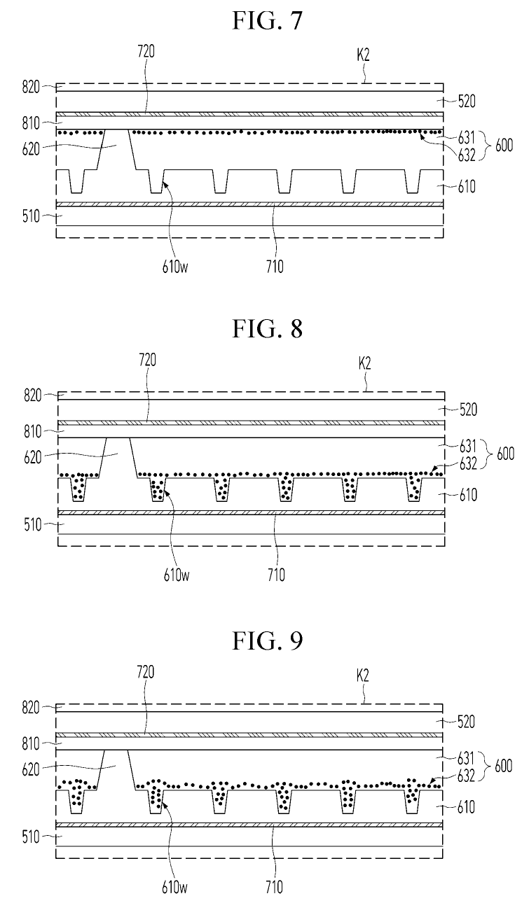

FIG. 6 is a waveform diagram showing a voltage of a signal applied to the first shutter electrode layer 710 and a voltage of a signal applied to the second shutter electrode layer 720 in the display device according to the implementation of the present disclosure, when the optical shutter panel ES is switched from the light-blocking mode to the light-transmission mode. FIGS. 7 to 12 are views sequentially showing a location of the electronic ink particles 632 in the display device according to the implementation of the present disclosure, when the optical shutter panel ES is switched from the light-blocking mode to the light-transmitting mode.

A method of driving the optical shutter panel ES of the display apparatus according to the implementation of the present disclosure will be described with reference to FIGS. 6 to 12. First, as shown in FIGS. 6 and 7, the method of driving the optical shutter panel ES of the display apparatus according to the implementation of the present disclosure can include a step of realizing the light-blocking mode LB mode in which a reference voltage Vo is applied to the second shutter electrode layer 720 and a light-blocking voltage Vb lower than the reference voltage Vo is applied to the first shutter electrode layer 710.

In the light-blocking mode LB mode, the electronic ink particles 632 can move toward the shutter adhesive layer 810 by a voltage difference between the first shutter electrode layer 710 and the second shutter electrode layer 720. For example, the electronic ink particles 632 can be disposed side by side on the lower surface of the second shutter electrode layer 720 in the light-blocking mode LB mode. Thus, in the method of driving the optical shutter panel ES of the display apparatus according to the implementation of the present disclosure, the external light passing through the shutter insulating layer 610 can be blocked by the electronic ink particles 632 in the light-blocking mode LB mode. Therefore, in the method of driving the optical shutter panel ES of the display apparatus according to the implementation of the present disclosure, the transmission areas TA can be recognized as an opaque area by the user in the light-blocking mode LB mode.

As shown in FIGS. 6 and 8, the method of driving the optical shutter panel ES of the display apparatus according to the implementation of the present disclosure can include a step of changing the light-blocking mode to a first intermediate mode C1 in which the reference voltage Vo is applied to the second shutter electrode layer 720 and a light-transmission voltage Vt higher than the reference voltage Vo is applied to the first shutter electrode layer 710 for first time.

In the first intermediate mode C1, the electronic ink particles 632 can move toward the shutter holes 610w of the shutter insulating layer 610 by a voltage difference between the first shutter electrode layer 710 and the second shutter electrode layer 720. The electronic ink particles 632 can move very quickly in the first intermediate mode C1 due to a large difference between the light-blocking voltage Vb and the light-transmission voltage Vt. Thus, in the method of driving the optical shutter panel ES of the display apparatus according to the implementation of the present disclosure, at least some of the electronic ink particles 632 can be disposed on the upper surface of the shutter insulating layer 610 in the first intermediate mode C1.

As shown in FIGS. 6 and 9, the method of driving the optical shutter panel ES of the display apparatus according to the implementation of the present disclosure can include a step of changing the first intermediate mode C1 to a second intermediate mode C2 in which the reference voltage Vo is applied to the second shutter electrode layer 720 and a first low voltage VL1 lower than the reference voltage Vo is applied to the first shutter electrode layer 710 for second time.

In the second intermediate mode C2, the electronic ink particles 632 can move toward the second shutter electrode layer 720 by a voltage difference between the first shutter electrode layer 710 and the second shutter electrode layer 720. Thus, in the method of driving the optical shutter panel ES of the display apparatus according to the implementation of the present disclosure, the electronic ink particles 632 can be spaced apart from the shutter insulating layer 610 in the second intermediate mode C2. A difference between the reference voltage Vo and the first low voltage VL1 can be smaller than a difference between the reference voltage Vo and the light-blocking voltage Vb. Therefore, in the method of driving the optical shutter panel ES of the display apparatus according to the implementation of the present disclosure, a moving speed of the electronic ink particles 632 in the second intermediate mode C2 can be slower than a moving speed of the electronic ink particles 632 in the first intermediate mode C1. The second time can be shorter than the first time. For example, in the method of driving the optical shutter panel ES of the display apparatus according to the implementation of the present disclosure, the electronic ink particles 632 can be disposed closer to the shutter insulating layer 610 than the second shutter electrode layer 720 in the second intermediate mode C2.

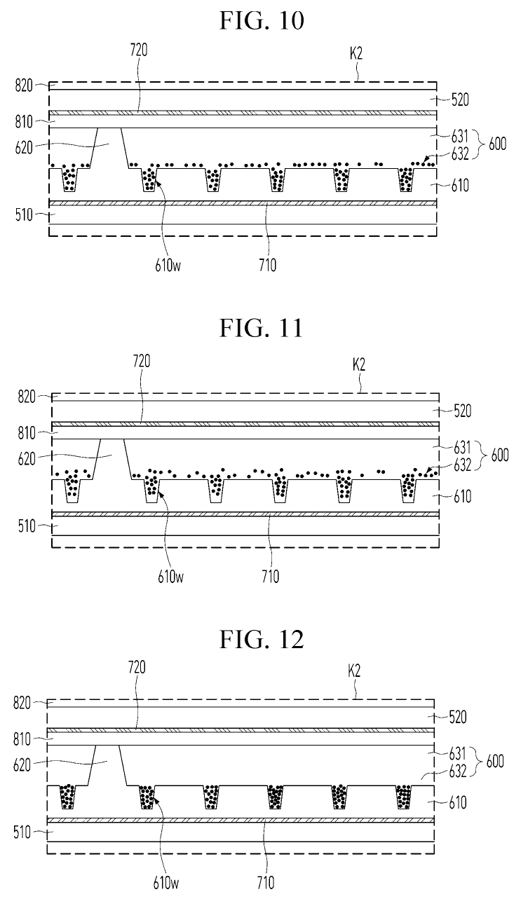

As shown in FIGS. 6 and 10, the method of driving the optical shutter panel ES of the display apparatus according to the implementation of the present disclosure can include a step of changing the second intermediate mode C2 to a third intermediate mode C3 in which the reference voltage Vo is applied to the second shutter electrode layer 720 and the light-transmission voltage Vt is applied to the first shutter electrode layer 710 for third time.

In the third intermediate mode C3, the electronic ink particles 632 can move toward the shutter holes 610w of the shutter insulating layer 610. The third time can be longer than the second time. For example, the third time can be a same as the first time. Thus, in the method of driving the optical shutter panel ES of the display apparatus according to the implementation of the present disclosure, the electronic ink particles 632 disposed close to the shutter insulating layer 610 in the second intermediate mode C2 can move inwardly of the shutter holes 610w. Therefore, in the method of driving the optical shutter panel ES of the display apparatus according to the implementation of the present disclosure, the amount of the electronic ink particles 632 disposed on the upper surface of the shutter insulating layer 610 in the third intermediate mode C3 can be reduced from the amount of the electronic ink particles 632 disposed on the upper surface of the shutter insulating layer 610 in the first intermediate mode C1.

As shown in FIGS. 6 and 11, the method of driving the optical shutter panel ES of the display apparatus according to the implementation of the present disclosure can include a step of changing the third intermediate mode C3 to a fourth intermediate mode C4 in which the reference voltage Vo is applied to the second shutter electrode layer 720 and a second low voltage VL2 lower than the reference voltage Vo is applied to the first shutter electrode layer 710.

As fourth intermediate mode C4, the electronic ink particles 632 can move toward the second shutter electrode layer 720. Thus, in the method of driving the optical shutter panel ES of the display apparatus according to the implementation of the present disclosure, the electronic ink particles 632 can be spaced apart from the shutter insulating layer 610 in the fourth intermediate mode C4. A difference between the reference voltage Vo and the second low voltage VL2 can be smaller than a difference between the reference voltage Vo and the first low voltage VL1. Therefore, in the method of driving the optical shutter panel ES of the display apparatus according to the implementation of the present disclosure, a moving speed of the electronic ink particles 632 in the fourth intermediate mode C4 can be slower than a moving speed of the electronic ink particles 632 in the second intermediate mode C2. For example, in the method of driving the optical shutter panel ES of the display apparatus according to the implementation of the present disclosure, the electronic ink particles 632 can be disposed very close to the shutter insulating layer 610 in the fourth intermediate mode C4. The fourth time can be shorter than the third time. For example, the fourth time can be a same as the second time.

As shown in FIGS. 6 and 12, the method of driving the optical shutter panel ES of the display apparatus according to the implementation of the present disclosure can include a step of changing the fourth intermediate mode C4 to a fifth intermediate mode C5 in which the reference voltage Vo is applied to the second shutter electrode layer 720 and a first high voltage VH1 higher than the reference voltage Vo is applied to the first shutter electrode layer 710 for a fifth time.

In the fifth intermediate mode C5, the electronic ink particles 632 can move toward the shutter holes 610w of the shutter insulating layer 610. A difference between the reference voltage Vo and the first high voltage VH1 can be smaller than a difference between the reference voltage Vo and the light-transmission voltage Vt. Thus, in the method of driving the optical shutter panel ES of the display apparatus according to the implementation of the present disclosure, a moving speed of the electronic ink particles 632 in the fifth intermediate mode C5 can be slower than a moving speed of the electronic ink particles 632 in the third intermediate mode C3. That is, in the method of driving the optical shutter panel ES of the display apparatus according to the implementation of the present disclosure, the electronic ink particles 632 disposed very close to the shutter insulating layer 610 in the fourth intermediate mode C4 can be slowly introduced inwardly of one of the shutter holes 610w. For example, in the method of driving the optical shutter panel ES of the display apparatus according to the implementation of the present disclosure, each of the shutter holes 610w can be completely filled by the electronic ink particles 632 in the fifth intermediate mode C5. And, in the method of driving the optical shutter panel ES of the display apparatus according to the implementation of the present disclosure, the electronic ink particles 632 disposed on the upper surface of the shutter insulating layer 610 can be significantly reduced in the fifth intermediate mode C5. For example, in the fifth intermediate mode C5, the electronic ink particles 632 cannot be disposed on the upper surface of the shutter insulating layer 610. The fifth time can be a same as the third time.

As shown in FIG. 6, the method of driving the optical shutter panel ES of the display apparatus according to the implementation of the present disclosure can include a step of changing the fifth intermediate mode C5 to a light-transmission mode LT mode in which the reference voltage Vo is applied to the second shutter electrode layer 720 and the light-transmission voltage Vt is applied to the first shutter electrode layer 710.

A location of the electronic ink particles 632 filling the shutter holes 610w in the fifth intermediate mode C5 can be maintained due to a voltage difference between the first shutter electrode layer 710 and the second shutter electrode layer 720 in the light-transmission mode LT mode. Thus, in the method of driving the optical shutter panel ES of the display apparatus according to the implementation of the present disclosure, the external light passing through the upper surface of the shutter insulating layer 610 can travel toward the transmission areas TA through the second shutter electrode layer 720 in the light-transmission mode LT mode. Therefore, in the method of driving the optical shutter panel ES of the display apparatus according to the implementation of the present disclosure, the light passing through the transmission areas TA can be provided to the user in the light-transmission mode LT mode. For example, in the method of driving the optical shutter panel ES of the display apparatus according to the implementation of the present disclosure, the display panel DP can be recognized as glass by the user due to the transmission areas TA in the light-transmission mode LT mode.

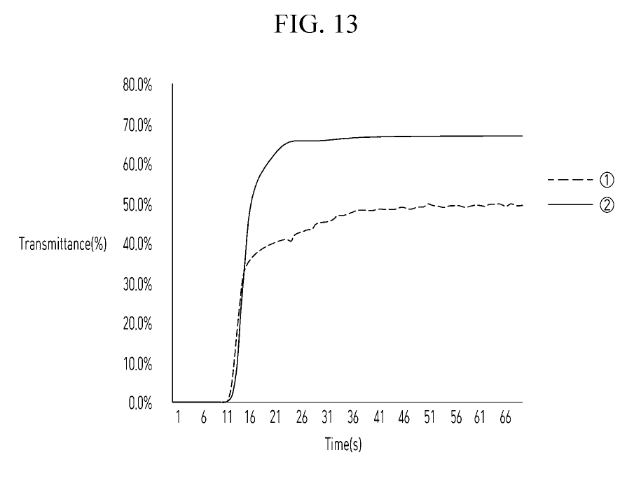

FIG. 13 is a graph showing transmittances of a first optical shutter panel ① that changes the light-blocking mode LB mode to the light-transmission mode LT mode without an intermediate mode C1-C5, and a second optical shutter panel ② that changes the light-blocking mode LB mode to the light-transmission mode LT mode with the intermediate modes C1-C5, in the light-transmission mode LT mode.

Referring to FIG. 13, the second optical shutter panel ② that changes the light-blocking mode LB mode to the light-transmission mode LT mode with the intermediate modes C1-C5 in the light-transmission mode LT mode can have a higher transmittance than the first optical shutter panel ① that changes the light-blocking mode LB mode to the light-transmission mode LT mode without an intermediate mode C1-C5 in the light-transmission mode LT mode. That is, in the display apparatus according to the implementation of the present disclosure, the transmittance in the light-transmission mode LT mode can be maximized by driving the optical shutter panel ES with a mode switching period MC period including the first to fifth intermediate mode C1-C5 between the light-blocking mode LB mode and the light-transmission mode LT mode. Therefore, in the display apparatus according to the implementation of the present disclosure, the luminance and the visibility of the actual object recognized by the user through the transmission areas TA of the display panel DP can be improved.

Accordingly, the display apparatus according to the implementation of the present disclosure can comprise the display panel DP on the optical shutter panel ES, wherein the optical shutter panel ES can include the first shutter substrate 510, the first shutter electrode layer 710, the shutter insulating layer 610, the electronic ink layer 630, the second shutter electrode layer 720 and the second shutter substrate 520, which are sequentially stacked, wherein the shutter insulating layer 610 can include the shutter holes 610w overlapping with the electronic ink layer 630, and wherein the optical shutter panel ES can be driven to change the light-blocking mode LB mode to the light-transmission mode LT mode by repeating the a positive voltage intermediate mode C1 and C3 in which a voltage higher than the reference voltage Vo applied to the second shutter electrode layer 720 is applied to the first shutter electrode layer 710 and a negative voltage intermediate mode C2 and C4 in which a voltage lower than the reference voltage Vo to the first shutter electrode layer 710 for a shorter time than the positive voltage intermediate mode C1 and C3. Thus, in the display apparatus according to the implementation of the present disclosure, the electronic ink particles 632 disposed outside the shutter holes 610w in the light-transmission mode LT mode can be minimized, and the transmittance in the light-transmission mode LT mode can be improved. Therefore, in the display apparatus according to the implementation of the present disclosure, the luminance and the visibility of the actual object recognized by the user through the transmission areas TA can be improved, when the image cannot be realized.

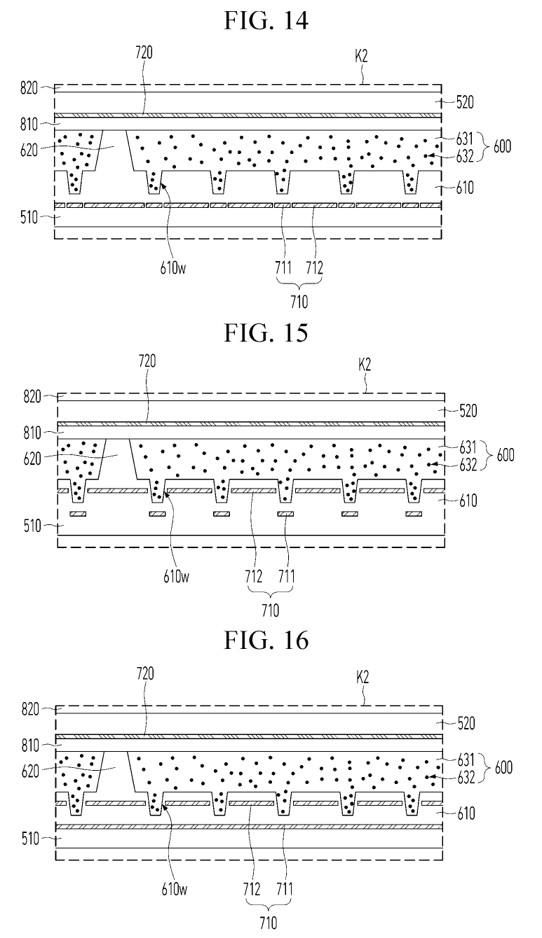

The display apparatus according to the implementation of the present disclosure is described a portion of the first shutter electrode layer 710 overlapping with the shutter holes 610w is in direct contact with a portion of the first shutter electrode layer 710 disposed between the shutter holes 610w. However, in the display apparatus according to another implementation of the present disclosure, the first shutter electrode layer 710 can have various structures. For example, in the display apparatus according to another implementation of the present disclosure, the first shutter electrode layer 710 can include first electrode patterns 711 overlapping with the shutter holes 610w and second electrode patterns 712 spaced apart from the first electrode patterns 711, as shown in FIG. 14.

The second electrode patterns 712 can be insulated from the first electrode patterns 711. A different signal from the first electrode patterns 711 can be applied to the second electrode patterns 712. For example, in the display apparatus according to another implementation of the present disclosure, the reference voltage Vo can be applied to the second shutter electrode layer 720, a voltage lower than the reference voltage Vo can be applied to the second electrode patterns 712 of the first shutter electrode layer 710, and a voltage higher than the reference voltage Vo can be applied to the first electrode patterns 711 of the first shutter electrode layer 710 in the second intermediate mode C2 and/or the fourth intermediate mode C4. Thus, in the display apparatus according to another implementation of the present disclosure, the electronic ink particles 632 disposed inside the shutter holes 610w can be suppressed in the second intermediate mode C2 and/or the fourth intermediate mode C4. That is, in the display apparatus according to another implementation of the present disclosure, the electronic ink particles 632 disposed on the upper surface of the shutter insulating layer 610 can be effectively moved in a process of switching from the light-blocking mode LB mode to the light-transmission mode LT mode. Therefore, in the display apparatus according to another implementation of the present disclosure, the transmittance in the light-transmission mode LT mode of the optical shutter panel ES can be effectively improved.

In the display apparatus according to another implementation of the present disclosure, the second electrode patterns 712 can be disposed closer to the upper surface of the shutter insulating layer 610 than the first electrode patterns 711, as shown in FIG. 15. For example, in the display apparatus according to another implementation of the present disclosure, a bottom surface of each shutter hole 610w toward the first shutter substrate 510 can be disposed closer to the first shutter substrate 510 than the second electrode patterns 712. Each of the second electrode patterns 712 can be disposed on a side wall of one of the shutter holes 610w. Thus, in the display apparatus according to another implementation of the present disclosure, strength of the electric field applied to a portion of the electronic ink layer 630 overlapping with the upper surface of the shutter insulating layer 610 can be increased in the second intermediate mode C2 and/or the fourth intermediate mode C4. Therefore, in the display apparatus according to another implementation of the present disclosure, the movement of the electronic ink particles 632 disposed inside each of the shutter holes 610w can be effectively suppressed in the second intermediate mode C2 and/or the fourth intermediate mode C4.

In the display apparatus according to another implementation of the present disclosure, each of the first electrode patterns 711 can include a region overlapping with one of the second electrode patterns 712. For example, in the display apparatus according to another implementation of the present disclosure, each of the first electrode patterns 711 can be in direct contact with adjacent first electrode pattern 711 by extending between the shutter holes 610w, as shown in FIG. 16. Thus, in the display apparatus according to another implementation of the present disclosure, occurrence of a region to which an electric field is not applied can be prevented. That is, in the display apparatus according to another implementation of the present disclosure, the movement of the electronic ink particles 632 disposed outside the shutter holes 610w can be effectively controlled in the second intermediate mode C2 and/or the fourth intermediate mode C4. Therefore, in the display apparatus according to another implementation of the present disclosure, the electronic ink particles 632 disposed on the upper surface of the shutter insulating layer 610 can be effective removed.

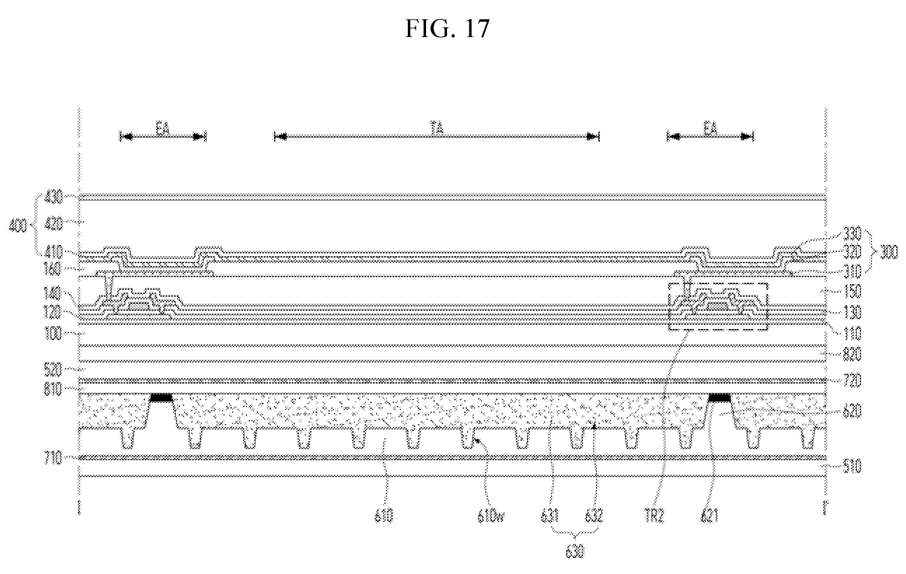

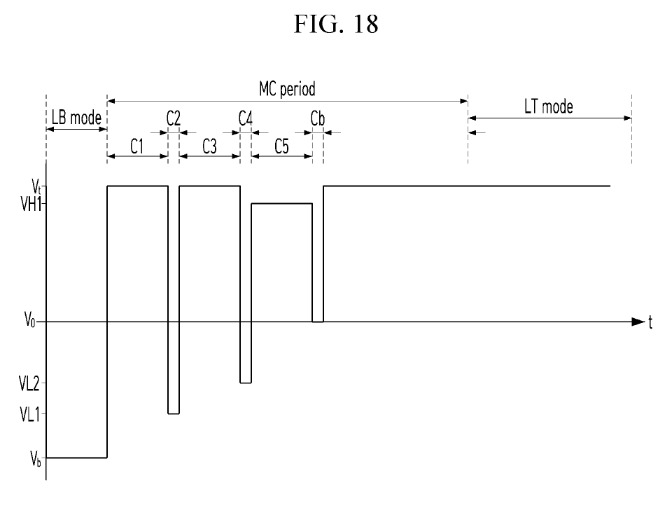

In the display apparatus according to another implementation of the present disclosure, light-blocking patterns 621 can be disposed between an upper surface of each shutter spacer 620 toward the second shutter electrode layer 720 and the shutter adhesive layer 810, as shown in FIG. 17. The light-blocking patterns 621 can include a material capable of blocking light. The light-blocking patterns 621 can include an insulating material. For example, the light-blocking patterns 621 can include a black dye, such as carbon black. Thus, in the display apparatus according to another implementation of the present disclosure, light passing through each shutter spacer 620 can be blocked by one of the light-blocking patterns 621. Therefore, in the display apparatus according to another implementation of the present disclosure, the distortion of the actual object due to the shutter spacers 620 can be effectively prevented.

The method of driving the optical shutter panel ES of the display apparatus according to the implementation of the present disclosure is described that the reference voltage Vo is applied to the second shutter electrode layer 720, and the fifth intermediate mode C5 in which the first high voltage VH1 is applied to the first shutter electrode layer 710 for the fifth time is changed to the light-transmission mode LT mode. However, in the method of driving the optical shutter panel ES of the display apparatus according to another implementation of the present disclosure, at least one intermediate mode can be arranged between the fifth intermediate mode C5 and the light-transmission mode LT mode. For example, in the display apparatus according to another implementation of the present disclosure, the fifth intermediate mode C5 can be changed to a buffer intermediate mode Cb in which the reference voltage Vo is applied to the first shutter electrode layer 710 and the second shutter electrode layer 720.

In the buffer intermediate mode Cb in which a voltage difference between the first shutter electrode layer 710 and the second shutter electrode layer 720 is 0, the electronic ink particles 632 can be moved by a repulsive force of the electronic ink particles 632. For example, in the method of driving the optical shutter panel ES of the display apparatus according to the implementation of the present disclosure, the electronic ink particles 632 disposed on the upper surface of the shutter insulating layer 610 can be slowly moved toward adjacent shutter hole 610w in the buffer intermediate mode Cb. Thus, in the method of driving the optical shutter panel ES of the display apparatus according to the implementation of the present disclosure, collision of the electronic ink particles 632 moving by the electric field can be prevented in the buffer intermediate mode Cb. Therefore, in the method of driving the optical shutter panel ES of the display apparatus according to the implementation of the present disclosure, the electronic ink particles 632 can be effectively gathered inside the shutter holes 610w in the buffer intermediate mode Cb.

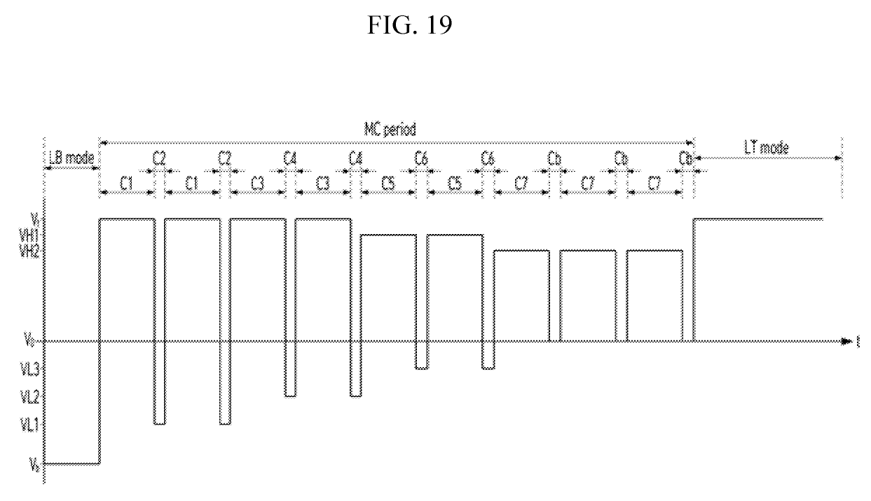

In the method of driving the optical shutter panel ES of the display apparatus according to the implementation of the present disclosure, a voltage applied to the first shutter electrode layer 710 can be gradually reduced in the intermediate modes C1, C3 and C5 in which a positive voltage is applied. For example, in the method of driving the optical shutter panel ES of the display apparatus according to the implementation of the present disclosure, the first intermediate mode C1 and the second intermediate mode C2 can be repeated twice, and the third intermediate mode C3 and the fourth intermediate mode C4 can be repeated twice, as shown in FIG. 19.

And, in the method of driving the optical shutter panel ES of the display apparatus according to the implementation of the present disclosure, the reference voltage Vo can be applied to the second shutter electrode layer 720 in the fifth intermediate mode C5, the fifth intermediate mode C5 can be changed to a sixth intermediate mode C6 in which a third low voltage VL3 lower than the reference voltage Vo is applied to the first shutter electrode 710 for a sixth time, and the fifth intermediate mode C5 and the sixth intermediate mode C6 can be repeated once. A voltage difference between the reference voltage Vo and the third low voltage VL3 can be smaller than a voltage difference between the reference voltage Vo and the second low voltage VL2.

Also, in the method of driving the optical shutter panel ES of the display apparatus according to the implementation of the present disclosure, the sixth intermediate mode C6 can be changed to a seventh intermediate mode C7 in which the reference voltage Vo is applied to the second shutter electrode layer 720 and a second high voltage VH2 higher than the reference voltage Vo is applied to the first shutter electrode layer 710 for a seventh time, the seventh intermediate mode C7 can be changed to the buffer intermediate mode Cb, and the seventh intermediate mode C7 and the buffer intermediate mode Cb can be repeated twice. A difference between the reference voltage Vo and the second high voltage VH2 can be smaller than a difference between the reference voltage Vo and the first high voltage VH1.

That is, in the method of driving the optical shutter panel ES of the display apparatus according to the implementation of the present disclosure, a voltage applied to the first shutter electrode layer 710 can be gradually reduced in the intermediate modes C1-C7 and Cb of the mode switching period MC period. Thus, in the method of driving the optical shutter panel ES of the display apparatus according to the implementation of the present disclosure, the collision of the electronic ink particles 632 moving by the electric field can be reduced, gradually. Therefore, in the method of driving the optical shutter panel ES of the display apparatus according to the implementation of the present disclosure, the electronic ink particles 632 disposed on the upper surface of the shutter insulating layer 610 can be effective removed by the mode switching period MC period.

In the result, the optical shutter panel of the display apparatus according to the implementations of the present disclosure can comprise the first shutter substrate, the first shutter electrode layer, the shutter insulating layer, the electronic ink layer, the second shutter electrode layer and the second shutter substrate, which are sequentially stacked, wherein the shutter insulating layer can include the shutter holes overlapping with the electronic ink layer, wherein a voltage higher than the reference voltage applied to the second shutter electrode layer and a voltage lower than the reference voltage can be alternately applied to the first shutter electrode layer, when the light-blocking mode is changed to the light-transmission mode, and wherein a time in which a voltage applied to the first shutter electrode layer is lower than a voltage applied to the second shutter electrode layer can be shorter than a time in which a voltage applied to the first shutter electrode layer higher than a voltage applied to the second shutter electrode layer. Thus, in the display apparatus according to the implementations of the present disclosure, the electronic ink particles disposed outside the shutter holes in the light-transmission mode can be reduced. Thereby, in the display apparatus according to the implementations of the present disclosure, the transmittance in the light-transmission mode can be improved. And, in the display apparatus according to the implementations of the present disclosure, low power operation can be possible, and power consumption can be reduced.

What is claimed is:

1. An optical shutter panel, comprising:
a second shutter substrate on a first shutter substrate;
an electronic ink layer between the first shutter substrate and the second shutter substrate;
a first shutter electrode layer between the first shutter substrate and the electronic ink layer, the first shutter electrode layer including first electrode patterns and second electrode patterns;
a shutter insulating layer between the first shutter electrode layer and the electronic ink layer, the shutter insulating layer including shutter holes overlapping with the first electrode patterns; and
a second shutter electrode layer between the electronic ink layer and the second shutter substrate,
wherein the second electrode patterns are disposed between the shutter holes and are insulated from the first electrode patterns.

2. The optical shutter panel according to claim 1, wherein a size of each second electrode pattern is different from a size of each first electrode pattern.

3. The optical shutter panel according to claim 1, wherein a distance between the first shutter substrate and each second electrode pattern is larger than a distance between the first shutter substrate and each first electrode pattern.

4. The optical shutter panel according to claim 3, wherein a bottom surface of each shutter hole protrudes toward the first shutter substrate and is disposed closer to the first shutter substrate than the second electrode patterns.

5. The optical shutter panel according to claim 3, wherein each of the first electrode patterns includes a region overlapping with one of the second electrode patterns.

6. The optical shutter panel according to claim 1, wherein the second electrode patterns include a same material as the first electrode patterns.

7. The optical shutter panel according to claim 1, further comprising a shutter adhesive layer between the electronic ink layer and the second shutter electrode layer.

8. The optical shutter panel according to claim 7, further comprising shutter spacers between the shutter insulating layer and the shutter adhesive layer,
wherein the electronic ink layer overlapping with the shutter holes is disposed between the shutter spacers.

9. A method of driving an optical shutter panel, comprising:
operating a light-blocking mode in which electronic ink particles of an electronic ink layer disposed between a first shutter electrode layer and a second shutter electrode layer are arranged side by side on a surface of the second shutter electrode layer, wherein the operating of the light-blocking mode comprises applying a light-blocking voltage to the first shutter electrode layer, wherein the light-blocking voltage is lower than a voltage applied the second shutter electrode layer;
changing the light-blocking mode to a first intermediate mode in which the electronic ink particles in the light-blocking mode move toward shutter holes of a shutter insulating layer disposed between the first shutter electrode layer and the electronic ink layer, wherein the changing of the light-blocking mode to the first intermediate mode comprises applying a first voltage to the first shutter electrode layer for a first time duration, wherein the first voltage is higher than the voltage applied to the second shutter electrode layer;
changing the first intermediate mode to a second intermediate mode in which the electronic ink particles in the first intermediate mode move toward the second shutter electrode layer, wherein the changing of the first intermediate mode to the second intermediate mode comprises applying a second voltage to the first shutter electrode layer for a second time duration, wherein the second voltage is lower than the voltage applied to the second shutter electrode layer;
changing the second intermediate mode to a third intermediate mode in which the electronic ink particles in the second intermediate mode move toward the shutter holes of the shutter insulating layer, wherein the changing of the second intermediate mode to the third intermediate mode comprises applying a third voltage to the first shutter electrode layer for a third time duration, wherein the third voltage is higher than the voltage applied to the second shutter electrode layer; and
changing the third intermediate mode to a light-transmission mode in which external light transmits between the shutter holes that is filled by the electronic ink particles, wherein the changing of the third intermediate mode to the light-transmission mode comprises applying a light-transmission voltage to the first shutter electrode layer, wherein the light-transmission voltage is higher than the voltage applied to the second shutter electrode layer,
wherein the second time duration is shorter than the first time duration and the third time duration.

10. The method of driving the optical shutter panel according to claim 9, wherein a voltage difference between the first shutter electrode layer and the second shutter electrode layer in the first intermediate mode is a same as a voltage difference between the first shutter electrode layer and the second shutter electrode layer in the light-transmission mode.

11. The method of driving the optical shutter panel according to claim 9, wherein a voltage difference between the first shutter electrode layer and the second shutter electrode layer in the second intermediate mode is smaller than a voltage difference between the first shutter electrode layer and the second shutter electrode layer in the light-blocking mode.

12. The method of driving the optical shutter panel according to claim 9, wherein a voltage difference between the first shutter electrode layer and the second shutter electrode layer in the third intermediate mode is smaller than a voltage difference between the first shutter electrode layer and the second shutter electrode layer in the first intermediate mode.

13. The method of driving the optical shutter panel according to claim 9, further comprising
changing the third intermediate mode to a fourth intermediate mode; and
changing the fourth intermediate mode to the light-transmission mode,
wherein a voltage difference between the first shutter electrode layer and the second shutter electrode layer is reduced in the fourth intermediate mode.

14. The method of driving the optical shutter panel according to claim 13, wherein a voltage applied to the first shutter electrode layer in the fourth intermediate mode is a same as the voltage applied the second shutter electrode layer.

15. The method of driving optical shutter panel according to claim 9, wherein the third time duration is a same as the first time duration.
